(19) United States
(12) Patent Application Publication
(10) Pub. No.: US 2024/0178801 A1
(43) Pub. Date: May 30, 2024

(54) Circuits And Methods For Receiving Data Signals Having Different Common-Mode Voltages

(71) Applicant: Altera Corporation, San Jose, CA (US)

(72) Inventor: Chee Hong Aw, Bayan Lepas (MY)

(73) Assignee: Altera Corporation, San Jose, CA (US)

(21) Appl. No.: 18/432,538

(22) Filed: Feb. 5, 2024

(51) Int. Cl. H03F 3/04; H03K 3/037; H03K 19/20

(52) U.S. Cl. CPC H03F 3/04; H03K 3/037; H03K 19/20

(57) ABSTRACT

A receiver circuit includes a first sense amplifier circuit that generates a first data signal based on a second data signal that has a first common-mode voltage during a first mode of operation. The receiver circuit includes a second sense amplifier circuit that generates a third data signal based on a fourth data signal that has a second common-mode voltage less than the first common-mode voltage during a second mode of operation. The receiver circuit includes a switch circuit that provides first data bits indicated by the first data signal to an output during the first mode of operation. The switch circuit provides second data bits indicated by the third data signal to the output during the second mode of operation.

### TECHNICAL FIELD

The present disclosure relates to circuits and methods for receiving data signals at a receiver that have different common-mode voltages.

### BACKGROUND

Configurable integrated circuits can be configured by users to implement desired custom logic functions. In a typical scenario, a logic designer uses computer-aided design (CAD) tools to design a custom circuit design. When the design process is complete, the computer-aided design tools generate configuration data containing configuration bits. The configuration data is then loaded into configuration memory elements that configure configurable logic circuits in the integrated circuit to perform the functions of the custom circuit design. Configurable integrated circuits can be used for co-processing in big-data or fast-data applications. For example, configurable integrated circuits can used in application acceleration tasks in a datacenter and can be reprogrammed during datacenter operation to perform different tasks.

### BRIEF DESCRIPTION OF DRAWINGS

FIG. 1 is a diagram that depicts an example of a receiver circuit that supports data input signals transmitted according to data transmission standards that use either a high input common-mode voltage or a low input common-mode voltage.

FIG. 2 is a diagram that depicts an example of a set-reset (SR) latch circuit that is an example of the switch circuit in the receiver circuit of FIG. 1.

FIG. 3 is a diagram that depicts an example of a switch circuit that is another example of the switch circuit in the receiver circuit of FIG. 1.

FIG. 4 is a diagram of an illustrative example of a configurable integrated circuit (IC).

FIG. 5 illustrates a block diagram of a system that can be used to implement a circuit design to be programmed into a programmable logic device using design software.

FIG. 6 is a diagram that depicts an example of a programmable logic device that includes a fabric die and a base die that are connected to one another via microbumps.

FIG. 7 is a block diagram illustrating a computing system configured to implement one or more aspects of the embodiments described herein.

### DETAILED DESCRIPTION

DDR5 (Double Data Rate 5) and LPDDR (low-power double data rate) are standards for synchronous dynamic random access memory (RAM). The DDR5 standard uses a high input common-mode voltage (i.e., a channel terminated with resistance to a high supply voltage VDD). The LPDDR standard uses a low input common-mode voltage (i.e., a channel terminated with resistance to a ground voltage VSS). As a result, the receiver design requirements are different for the DDR5 and LPDDR standards. DDR5 typically uses a receiver design that is based on an input pair of n-type field effect transistors (FETs), because N-type FETs can operate with a high input common-mode voltage level for optimum input signal amplification gain. LPDDR typically uses a receiver design that is based on an input pair of p-type FETs. An integrated circuit that is designed to receive inputs signals according to both the DDR5 and LPDDR standards typically includes one receiver configured to receive signals according to the DDR5 standard and a second receiver configured to receive signals according to the LPDDR standard.

In some types of integrated circuits, it would be desirable to provide one receiver that supports both the DDR5 and the LPDDR standards to reduce power consumption and circuit layout area. According to some examples disclosed herein, a receiver circuit is provided that can resolve data bits in input signals that are transmitted according to data transmission standards (such as DDR5 and LPDDR5) that use high or low input common-mode voltages. The receiver circuit includes two latch-type voltage sense amplifier circuits. The first sense amplifier circuit includes a differential pair of n-type transistors. The first sense amplifier circuit resolves data bits in an input signal using the differential pair of n-type transistors when the input signal has a high input common-mode voltage (DDR5). The second sense amplifier circuit includes a differential pair of p-type transistors. The second sense amplifier circuit resolves data bits in the input signal using the differential pair of p-type transistors when the input signal has a low input common-mode voltage (LPDDR). The receiver circuit also includes a switch circuit. The switch circuit provides the output of the first sense amplifier circuit or the output of the second sense amplifier circuit to a deserializer circuit. The receiver circuit uses substantially less power and less circuit area compared to using separate receiver circuits for standards that support high and low input common-mode voltages.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially less configurable features than soft logic or no configurable features.

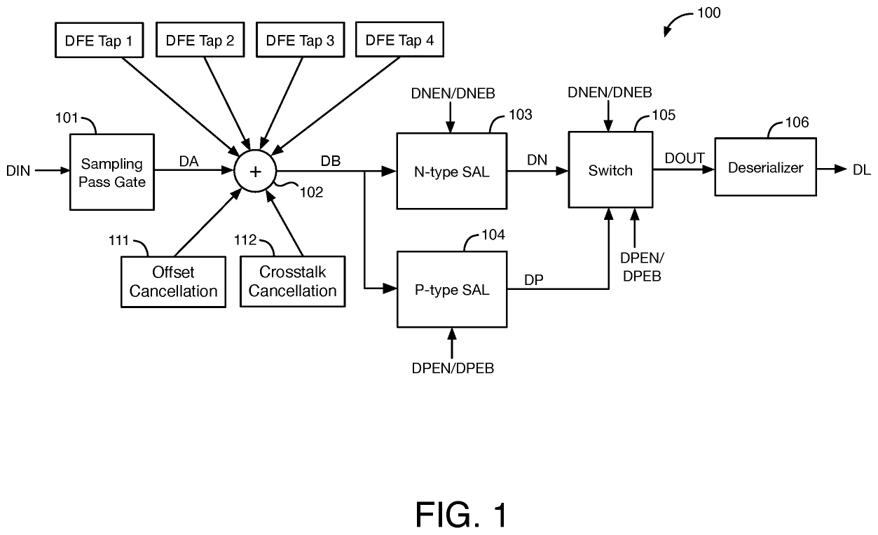

FIG. 1 is a diagram that depicts an example of a receiver circuit 100 that supports data input signals transmitted according to data transmission standards that use either a high input common-mode voltage or a low input common-mode voltage. Receiver circuit 100 of Figure (FIG.) 1 can be provided in any type of integrated circuit (IC), such as a configurable IC (e.g., a field programmable gate array (FPGA) or programmable logic device), a microprocessor IC, a graphics processing unit IC, a memory IC, an application specific IC, a transceiver IC, a memory IC, etc.

Receiver circuit 100 includes a sampling pass gate circuit 101, a decision feedback equalizer (DFE) combiner circuit 102, an n-type voltage sense amplifier latch (SAL) circuit 103, a p-type voltage sense amplifier latch (SAL) circuit 104, a switch circuit 105, and a deserializer circuit 106. SAL circuits 103 and 104 can be referred to and used as sense amplifier circuits, as latch circuits, and/or as comparator circuits. The SAL circuits 103 and 104 can be one of multiple different types of sense amplifier latch circuits, such as double-tail voltage sense amplifiers, latch-type voltage sense amplifiers, or strong arm latches. Receiver circuit 100 also receives decision feedback equalizer (DFE) taps 1, 2, 3, and 4. Receiver circuit 100 further receives offset cancellation values 111 and crosstalk cancellation values 112.

Receiver circuit 100 can resolve data bits in input signals that are transmitted according to data transmission standards that use either a high input common-mode voltage (such as DDR5) or a low input common-mode voltage (such as LPDDR5). Prior to receiving an input signal containing data bits that are transmitted according to a data transmission standard that uses a high common-mode voltage, the n-type SAL circuit 103 is enabled by enable signals DNEN and DNEB, and the p-type SAL circuit 104 is disabled by enable signals DPEN and DPEB. Prior to receiving an input signal containing data bits that are transmitted according to a data transmission standard that uses a low common-mode voltage, the n-type SAL circuit 103 is disabled by enable signals DNEN and DNEB, and the p-type SAL circuit 104 is enabled by enable signals DPEN and DPEB, as described in further detail below.

Initially, an input signal DIN indicating data bits is transmitted to receiver circuit 100 in the IC from a source that is external to the IC. The input data signal DIN is provided to an input of the sampling pass gate circuit 101. The sampling pass gate circuit 101 samples the data bits in the input signal DIN to generate sampled data bits in an output signal DA. The output signal DA is provided to an input of the DFE combiner circuit 102.

The DFE combiner circuit 102 also receives the four DFE taps 1-4. The DFE taps 1-4 can correspond to 4 previously received (and/or subsequently received) and sampled bits in signal DA. The DFE combiner circuit 102 adds and/or subtracts the DFE taps 1-4 to and/or from a current bit in signal DA to generate the next data bit in an output signal DB that has reduced inter-symbol interference (ISI) compared to the current data bit in signal DA. In other examples, DFE combiner circuit 102 can add and/or subtract more or less than 4 taps to each data bit in signal DA to generate the next data bit in signal DB. DFE combiner circuit 102 can also subtract offset cancellation values 111 and/or crosstalk cancellation values 112 from signal DA to generate the data bits in output signal DB with less offset and/or crosstalk noise.

DFE combiner circuit 102 causes signal DB to be a differential signal that is provided to inputs of n-type SAL circuit 103 and to inputs of p-type SAL circuit 104. As discussed above, if the input signal DIN contains data bits that are transmitted according to a data transmission standard that uses a high common-mode voltage (such as DDR5), the n-type SAL circuit 103 is enabled by enable signals DNEN and DNEB during a first mode of operation, and the p-type SAL circuit 104 is disabled by enable signals DPEN and DPEB. The n-type SAL circuit 103 amplifies signal DB using a differential pair of n-channel transistors to generate an output signal DN that indicates the data bits from signal DB. Signal DN is provided to switch circuit 105. Switch circuit 105 is also controlled by the 4 enable signals DNEN, DNEB, DPEN, and DPEB. When the n-type SAL circuit 103 amplifies signal DB to generate signal DN during the first mode of operation, the switch circuit 105 provides the data bits indicated by signal DN to output signal DOUT. Deserializer circuit 106 then converts the serial data bits indicated by signal DOUT into parallel data bits in signals DL. Switch circuit 105 is also referred to herein as a multiplexer circuit.

If the input signal DIN contains data bits that are transmitted according to a data transmission standard that uses a low common-mode voltage (such as LPDDR), the n-type SAL circuit 103 is disabled by enable signals DNEN and DNEB, and the p-type SAL circuit 104 is enabled by enable signals DPEN and DPEB during a second mode of operation. The p-type SAL circuit 104 amplifies signal DB using a differential pair of p-channel transistors to generate an output signal DP that indicates the data bits from signal DB. Signal DP is provided to switch circuit 105. When the p-type SAL circuit 104 amplifies signal DB to generate signal DP during the second mode of operation, the switch circuit 105 provides the data bits indicated by signal DP to output signal DOUT. Deserializer circuit 106 then converts the serial data bits indicated by signal DOUT into parallel data bits in signals DL.

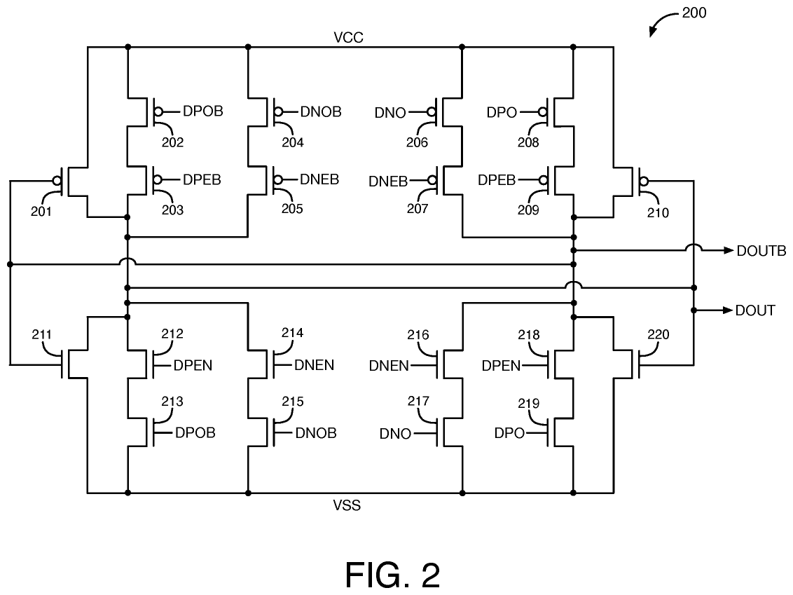

FIG. 2 is a diagram that depicts an example of a set-reset (SR) latch circuit 200. The SR latch circuit 200 of FIG. 2 is an example of a switch circuit that can be used as the switch circuit 105 in the receiver circuit 100 of FIG. 1. The SR latch circuit 200 includes p-type (p-channel) field effect transistors (FETs) 201-210 and n-type (n-channel) FETs 211-220. The SR latch circuit 200 includes two cross-coupled inverter circuits. The first inverter includes transistors 201 and 211, and the second inverter includes transistors 210 and 220. The first and second inverters are coupled to generate a differential output signal DOUT and DOUTB at the outputs of the SR latch circuit 200.

The SR latch circuit 200 also includes pull-up p-channel transistors 202-209 and pull-down n-channel transistors 212-219. P-channel transistors 202, 203, 204, 205, 206, 207, 208, and 209 are controlled by signals DPOB, DPEB, DNOB, DNEB, DNO, DNEB, DPO, and DPEB, respectively. N-channel transistors 212, 213, 214, 215, 216, 217, 218, and 219 are controlled by signals DPEN, DPOB, DNEN, DNOB, DNEN, DNO, DPEN, and DPO respectively. Signals DPO and DPOB are the differential output signal of the p-type SAL circuit 104 that indicates the data bits from signal DB in the example of FIG. 2. Thus, signal DP in FIG. 1 is the differential signal DPO/DPOB in FIG. 2. Signals DNO and DNOB are the differential output signal of the n-type SAL circuit 103 that indicates the data bits from signal DB in the example of FIG. 2. Thus, signal DN in FIG. 1 is the differential signal DNO/DNOB in FIG. 2.

When the n-type SAL circuit 103 is enabled by enable signals DNEN and DNEB in the first mode of operation, and the p-type SAL circuit 104 is disabled by enable signals DPEN and DPEB, enable signal DNEB enables transistors 205 and 207, enable signal DNEN enables transistors 214 and 216, enable signal DPEB disables transistors 203 and 209, and enable signal DPEN disables transistors 212 and 218. When transistors 205, 207, 214, and 216 are enabled, and transistors 203, 209, 212, and 218 are disabled, the data bits indicated by the differential output signal DNO/DNOB of the n-type SAL circuit 103 are stored in the inverters, and SR latch circuit 200 transmits the data bits indicated by the differential output signal DNO/DNOB and stored in the inverters to differential output signal DOUT/DOUTB.

When the n-type SAL circuit 103 is disabled by enable signals DNEN and DNEB, and the p-type SAL circuit 104 is enabled by enable signals DPEN and DPEB in the second mode of operation, enable signal DNEB disables transistors 205 and 207, enable signal DNEN disables transistors 214 and 216, enable signal DPEB enables transistors 203 and 209, and enable signal DPEN enables transistors 212 and 218. When transistors 205, 207, 214, and 216 are disabled, and transistors 203, 209, 212, and 218 are enabled, the data bits indicated by the differential output signal DPO/DPOB of the p-type SAL circuit 104 are stored in the inverters, and SR latch circuit 200 transmits the data bits indicated by the differential output signal DPO/DPOB and stored in the inverters to differential output signal DOUT/DOUTB.

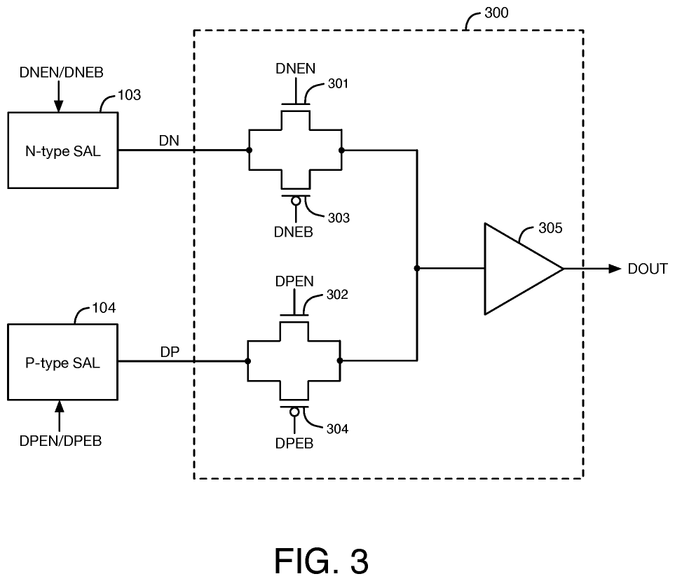

FIG. 3 is a diagram that depicts an example of a switch circuit 300. The switch circuit 300 of FIG. 3 is an example of a switch circuit that can be used as the switch circuit 105 in the receiver circuit 100 of FIG. 1. Switch circuit 300 is also referred to as a multiplexer circuit. The switch circuit 300 includes p-channel field effect transistors (FETs) 303-304 and n-channel FETs 301-302. Transistors 301 and 303 are coupled in parallel as a first pass gate circuit between n-type SAL circuit 103 and an input of a buffer circuit 305. Transistors 302 and 304 are coupled in parallel as a second pass gate circuit between p-type SAL circuit 104 and an input of buffer circuit 305. Buffer circuit 305 generates the output signal DOUT of the switch circuit 300.

When the n-type SAL circuit 103 is enabled by enable signals DNEN and DNEB in the first mode of operation, and the p-type SAL circuit 104 is disabled by enable signals DPEN and DPEB, enable signal DNEB enables transistor 303, enable signal DNEN enables transistor 301, enable signal DPEB disables transistor 304, and enable signal DPEN disables transistor 302. When transistors 302 and 304 are disabled, the second pass gate circuit is off. When transistors 301 and 303 are enabled, the first pass gate circuit is on, and the first pass gate circuit transmits the output signal DN of the n-type SAL circuit 103 to the input of buffer circuit 305. Buffer circuit 305 buffers the data bits indicated by output signal DN to generate data bits in the output signal DOUT.

When the n-type SAL circuit 103 is disabled by enable signals DNEN and DNEB, and the p-type SAL circuit 104 is enabled by enable signals DPEN and DPEB in the second mode of operation, enable signal DNEB disables transistor 303, enable signal DNEN disables transistor 301, enable signal DPEB enables transistor 304, and enable signal DPEN enables transistor 302. When transistors 301 and 303 are disabled, the first pass gate circuit is off. When transistors 302 and 304 are enabled, the second pass gate circuit is on, and the second pass gate circuit transmits the output signal DP of the p-type SAL circuit 104 to the input of buffer circuit 305. Buffer circuit 305 buffers the data bits indicated by output signal DP to generate data bits in the output signal DOUT.

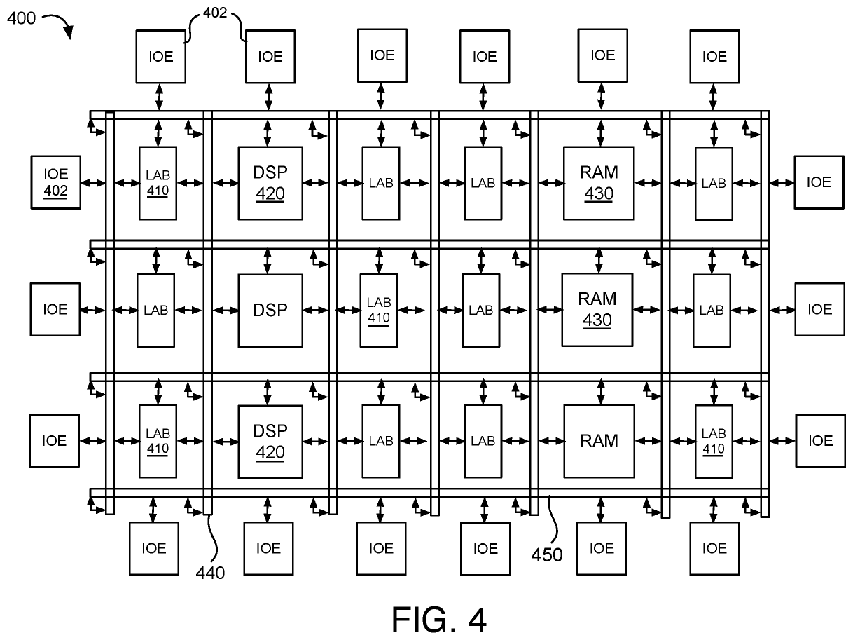

FIG. 4 is a diagram of an illustrative example of a configurable integrated circuit (IC) 400. Configurable IC 400 is an example of an IC that can include the circuitry disclosed herein with respect to FIGS. 1, 2 and/or 3. As shown in FIG. 4, the configurable integrated circuit 400 includes a two-dimensional array of configurable logic circuit blocks, including logic array blocks (LABs) 410 and other configurable logic circuit blocks, such as random access memory (RAM) blocks 430 and digital signal processing (DSP) blocks 420, for example. Configurable logic circuit blocks, such as LABs 410, can include smaller configurable regions (e.g., configurable logic elements, configurable logic blocks, or adaptive logic modules (ALMs)) that receive input signals and perform custom functions on the input signals to produce output signals.

The configurable integrated circuit 400 also includes programmable interconnect circuitry in the form of vertical routing channels 440 (i.e., interconnects formed along a vertical axis of configurable integrated circuit 400) and horizontal routing channels 450 (i.e., interconnects formed along a horizontal axis of configurable integrated circuit 400), each routing channel including at least one track to route at least one wire. One or more of the routing channels 440 and/or 450 can be part of a network-on-chip (NOC) having router circuits.

In addition, the configurable integrated circuit 400 has input/output elements (IOEs) 402 for driving signals off of configurable integrated circuit 400 and for receiving signals from other devices. Input/output elements 402 can include parallel input/output circuitry, serial data transceiver circuitry, differential receiver and transmitter circuitry, or other circuitry used to connect one integrated circuit to another integrated circuit. Input/output elements 402 can include general purpose input/output (GPIO) circuitry (e.g., on the top and bottoms edges of IC 400), high-speed input/output (HSIO) circuitry (e.g., on the left edge of IC 400), and on-package input/output (OPIOs) circuitry (e.g., on the right edge of IC 400).

As shown, input/output elements 402 can be located around the periphery of the IC. If desired, the configurable integrated circuit 400 can have input/output elements 402 arranged in different ways. For example, input/output elements 402 can form one or more columns of input/output elements that can be located anywhere on the configurable integrated circuit 400 (e.g., distributed evenly across the width of the configurable integrated circuit). If desired, input/output elements 402 can form one or more rows of input/output elements (e.g., distributed across the height of the configurable integrated circuit). Alternatively, input/output elements 402 can form islands of input/output elements that can be distributed over the surface of the configurable integrated circuit 400 or clustered in selected areas.

Note that other routing topologies, besides the topology of the interconnect circuitry depicted in FIG. 4, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 400, fractional global wires such as wires that span part of configurable integrated circuit 400, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 400 can also contain programmable memory elements. The memory elements can be loaded with configuration data (also called programming data) using input/output elements (IOEs) 402. Once loaded, the memory elements each provide a corresponding static control signal that controls the operation of an associated functional block (e.g., LABs 410, DSP 420, RAM 430, or input/output elements 402).

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 400 can include configuration memory that is organized in sectors, whereby a sector can include the configuration bits that specify the function and/or interconnections of the subcomponents and wires in or crossing that sector. Each sector can include separate data and address registers.

The configurable IC 400 of FIG. 4 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

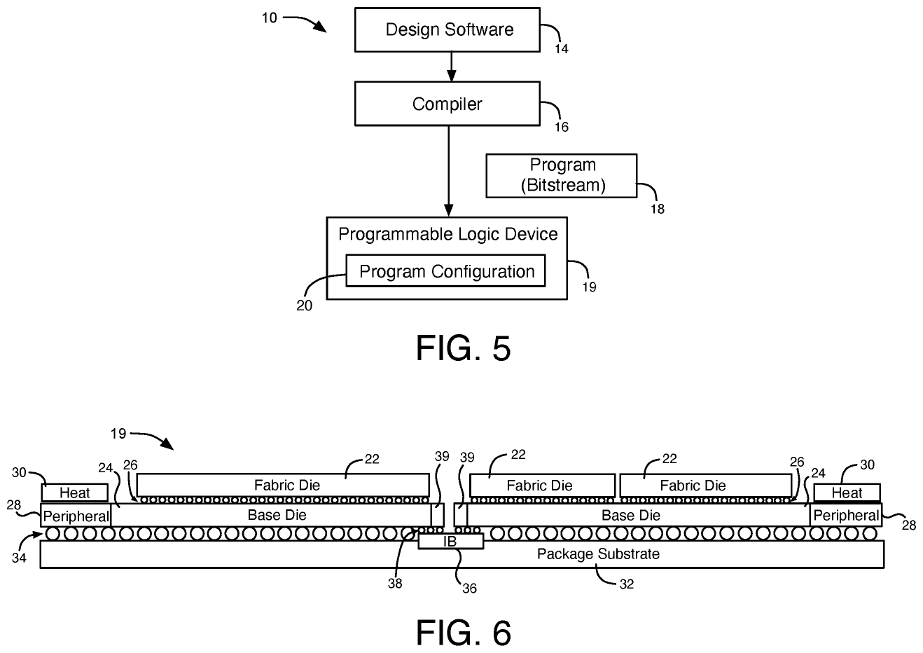

FIG. 5 illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6, but many others can be used, and it should be understood that this disclosure is intended to encompass any suitable programmable logic device where programmable logic fabric and fabric support circuitry are at least partially separated on different integrated circuit die.

FIG. 6 is a diagram that depicts an example of the programmable logic device 19 that includes three fabric die 22 and two base die 24 that are connected to one another via microbumps 26. In the example of FIG. 6, at least some of the programmable logic fabric of the programmable logic device 19 is in the three fabric die 22, and at least some of the fabric support circuitry that operates the programmable logic fabric is in the two base die 24. For example, some of the circuitry of configurable IC 400 shown in FIG. 4 (e.g., LABs 410, DSP 420, and RAM 430) can be located in the fabric die 22 and some of the circuitry of IC 400 (e.g., input/output elements 402) can be located in the base die 24.

Although the fabric die 22 and base die 24 appear in a one-to-one relationship or a two-to-one relationship in FIG. 6, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

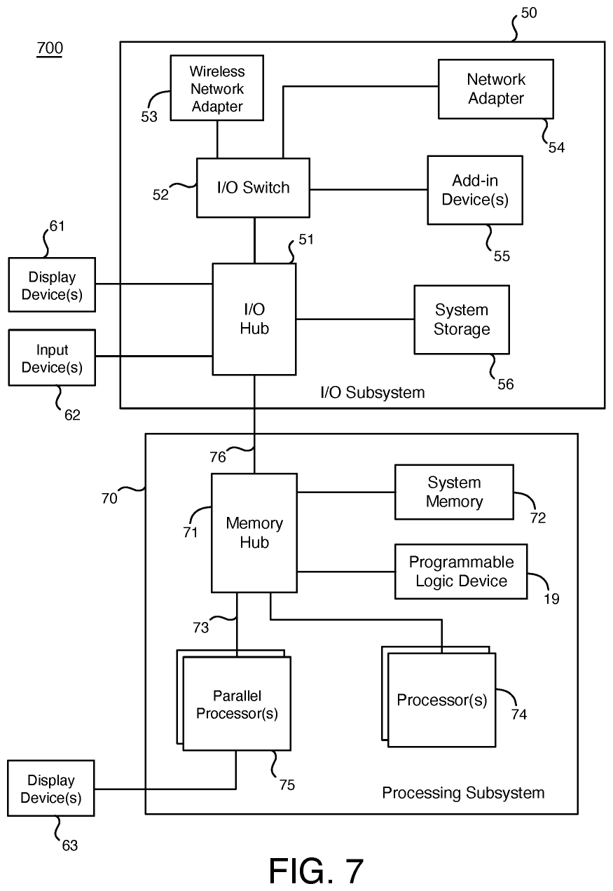

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is a receiver circuit comprising a first sense amplifier circuit that generates a first data signal based on a second data signal that has a first common-mode voltage during a first mode of operation; a second sense amplifier circuit that generates a third data signal based on a fourth data signal that has a second common-mode voltage less than the first common-mode voltage during a second mode of operation; and a switch circuit that provides first data bits indicated by the first data signal to an output during the first mode of operation, wherein the switch circuit provides second data bits indicated by the third data signal to the output during the second mode of operation.

In Example 2, the receiver circuit of Example 1 may optionally include, wherein the switch circuit comprises a first inverter circuit and a second inverter circuit coupled to the first inverter circuit.

In Example 3, the receiver circuit of any one of Examples 1-2 may optionally include, wherein the switch circuit is a set-reset latch.

In Example 4, the receiver circuit of any one of Examples 1-3 may optionally include, wherein the switch circuit comprises a first pull-up transistor and a first pull-down transistor that are controlled by the first data signal and that are coupled to the output.

In Example 5, the receiver circuit of Example 4 may optionally include, wherein the switch circuit further comprises a second pull-up transistor and a second pull-down transistor that are controlled by the third data signal and that are coupled to the output.

In Example 6, the receiver circuit of any one of Examples 1-5 may optionally include, wherein the switch circuit comprises a first pass gate coupled to the first sense amplifier circuit, and wherein the switch circuit further comprises a second pass gate coupled to the second sense amplifier circuit.

In Example 7, the receiver circuit of Example 6 may optionally include, wherein the switch circuit further comprises a buffer circuit that is coupled to the first pass gate and to the second pass gate.

In Example 8, the receiver circuit of any one of Examples 1-7 may optionally include, wherein the first sense amplifier circuit is an n-type latch, and wherein the second sense amplifier circuit is a p-type latch.

In Example 9, the receiver circuit of any one of Examples 1-8 further comprises a decision feedback equalizer circuit that generates the second data signal during the first mode of operation and that generates the fourth data signal during the second mode of operation.

Example 10 is a method for resolving data using a receiver circuit, the method comprising: generating a first data signal based on a second data signal having a first common-mode voltage using a first latch circuit in the receiver circuit during a first mode of operation; providing first bits indicated by the first data signal to an output using a switch circuit in the receiver circuit during the first mode of operation; generating a third data signal based on a fourth data signal having a second common-mode voltage that is less than the first common-mode voltage using a second latch circuit in the receiver circuit during a second mode of operation; and providing second bits indicated by the third data signal to the output using the switch circuit during the second mode of operation.

In Example 11, the method of Example 10 further comprises: generating the second data signal based on an input signal using a decision feedback equalizer in the first mode of operation; and generating the fourth data signal based on the input signal using the decision feedback equalizer in the second mode of operation.

In Example 12, the method of any one of Examples 10-11 may optionally include, wherein providing the first bits indicated by the first data signal to the output comprises storing the first bits in cross-coupled inverters in the switch circuit during the first mode of operation, and wherein providing the second bits indicated by the third data signal to the output comprises storing the second bits in the cross-coupled inverters.

In Example 13, the method of any one of Examples 10-12 may optionally include, wherein providing the first bits indicated by the first data signal to the output comprises providing the first bits through a first pass gate in the switch circuit to a buffer circuit during the first mode of operation.

In Example 14, the method of Example 13 may optionally include, wherein providing the second bits indicated by the third data signal to the output comprises providing the second bits through a second pass gate in the switch circuit to the buffer circuit during the second mode of operation.

In Example 15, the method of any one of Examples 10-14, wherein the first latch circuit is a first sense amplifier latch, and wherein the second latch circuit is a second sense amplifier latch.

Example 16 is an integrated circuit comprising a receiver circuit, wherein the receiver circuit comprises: a first sense amplifier latch circuit that outputs first data bits based on a first input signal that comprises a first common-mode voltage when the first sense amplifier latch circuit is enabled; a second sense amplifier latch circuit that outputs second data bits based on a second input signal that comprises a second common-mode voltage when the second sense amplifier latch circuit is enabled; and a multiplexer circuit that outputs the first data bits when the first sense amplifier latch circuit is enabled, wherein the multiplexer circuit outputs the second data bits when the second sense amplifier latch circuit is enabled.

In Example 17, the integrated circuit of Example 16, wherein the multiplexer circuit comprises a first pass gate circuit that transmits the first data bits when the first sense amplifier latch circuit is enabled, and wherein the multiplexer circuit further comprises a second pass gate circuit that transmits the second data bits when the second sense amplifier latch circuit is enabled.

In Example 18, the integrated circuit of any one of Examples 16-17 may optionally include, wherein the multiplexer circuit comprises cross-coupled inverters that store the first data bits when the first sense amplifier circuit is enabled and that store the second data bits when the second sense amplifier latch circuit is enabled.

In Example 19, the integrated circuit of any one of Examples 16-18 may optionally include, wherein the multiplexer circuit comprises a first pull-up transistor and a first pull-down transistor that are controlled by the first data bits output by the first sense amplifier latch circuit, and wherein the multiplexer circuit further comprises a second pull-up transistor and a second pull-down transistor that are controlled by the second data bits output by the second sense amplifier latch circuit.

In Example 20, the integrated circuit of any one of Examples 16-19 may optionally include, wherein the multiplexer circuit outputs the first data bits in response to a first enable signal, and wherein the multiplexer circuit outputs the second data bits in response to a second enable signal.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. A receiver circuit comprising:
a first sense amplifier circuit that generates a first data signal based on a second data signal that has a first common-mode voltage during a first mode of operation;
a second sense amplifier circuit that generates a third data signal based on a fourth data signal that has a second common-mode voltage that is less than the first common-mode voltage during a second mode of operation; and
a switch circuit that provides first data bits indicated by the first data signal to an output during the first mode of operation, wherein the switch circuit provides second data bits indicated by the third data signal to the output during the second mode of operation.

2. The receiver circuit of claim 1, wherein the switch circuit comprises a first inverter circuit and a second inverter circuit coupled to the first inverter circuit.

3. The receiver circuit of claim 1, wherein the switch circuit is a set-reset latch.

4. The receiver circuit of claim 1, wherein the switch circuit comprises a first pull-up transistor and a first pull-down transistor that are controlled by the first data signal and that are coupled to the output.

5. The receiver circuit of claim 4, wherein the switch circuit further comprises a second pull-up transistor and a second pull-down transistor that are controlled by the third data signal and that are coupled to the output.

6. The receiver circuit of claim 1, wherein the switch circuit comprises a first pass gate coupled to the first sense amplifier circuit, and wherein the switch circuit further comprises a second pass gate coupled to the second sense amplifier circuit.

7. The receiver circuit of claim 6, wherein the switch circuit further comprises a buffer circuit that is coupled to the first pass gate and to the second pass gate.

8. The receiver circuit of claim 1, wherein the first sense amplifier circuit is an n-type latch, and wherein the second sense amplifier circuit is a p-type latch.

9. The receiver circuit of claim 1 further comprising:
a decision feedback equalizer circuit that generates the second data signal during the first mode of operation and that generates the fourth data signal during the second mode of operation.

10. A method for resolving data using a receiver circuit, the method comprising:
generating a first data signal based on a second data signal having a first common-mode voltage using a first latch circuit in the receiver circuit during a first mode of operation;
providing first bits indicated by the first data signal to an output using a switch circuit in the receiver circuit during the first mode of operation;
generating a third data signal based on a fourth data signal having a second common-mode voltage that is less than the first common-mode voltage using a second latch circuit in the receiver circuit during a second mode of operation; and
providing second bits indicated by the third data signal to the output using the switch circuit during the second mode of operation.

11. The method of claim 10 further comprising:
generating the second data signal based on an input signal using a decision feedback equalizer in the first mode of operation; and
generating the fourth data signal based on the input signal using the decision feedback equalizer in the second mode of operation.

12. The method of claim 10, wherein providing the first bits indicated by the first data signal to the output comprises storing the first bits in cross-coupled inverters in the switch circuit during the first mode of operation, and wherein providing the second bits indicated by the third data signal to the output comprises storing the second bits in the cross-coupled inverters.

13. The method of claim 10, wherein providing the first bits indicated by the first data signal to the output comprises providing the first bits through a first pass gate in the switch circuit to a buffer circuit during the first mode of operation.

14. The method of claim 13, wherein providing the second bits indicated by the third data signal to the output comprises providing the second bits through a second pass gate in the switch circuit to the buffer circuit during the second mode of operation.

15. The method of claim 10, wherein the first latch circuit is a first sense amplifier latch, and wherein the second latch circuit is a second sense amplifier latch.

16. An integrated circuit comprising a receiver circuit, wherein the receiver circuit comprises:
a first sense amplifier latch circuit that outputs first data bits based on a first input signal that comprises a first common-mode voltage when the first sense amplifier latch circuit is enabled;
a second sense amplifier latch circuit that outputs second data bits based on a second input signal that comprises a second common-mode voltage when the second sense amplifier latch circuit is enabled; and
a multiplexer circuit that outputs the first data bits when the first sense amplifier latch circuit is enabled, wherein the multiplexer circuit outputs the second data bits when the second sense amplifier latch circuit is enabled.

17. The integrated circuit of claim 16, wherein the multiplexer circuit comprises a first pass gate circuit that transmits the first data bits when the first sense amplifier latch circuit is enabled, and wherein the multiplexer circuit further comprises a second pass gate circuit that transmits the second data bits when the second sense amplifier latch circuit is enabled.

18. The integrated circuit of claim 16, wherein the multiplexer circuit comprises cross-coupled inverters that store the first data bits when the first sense amplifier circuit is enabled and that store the second data bits when the second sense amplifier latch circuit is enabled.

19. The integrated circuit of claim 16, wherein the multiplexer circuit comprises a first pull-up transistor and a first pull-down transistor that are controlled by the first data bits output by the first sense amplifier latch circuit, and wherein the multiplexer circuit further comprises a second pull-up transistor and a second pull-down transistor that are controlled by the second data bits output by the second sense amplifier latch circuit.

20. The integrated circuit of claim 16, wherein the multiplexer circuit outputs the first data bits in response to a first enable signal, and wherein the multiplexer circuit outputs the second data bits in response to a second enable signal.
